(19) United States
(12) Patent Application Publication
(10) Pub. No.: US 2016/0181111 A1
(43) Pub. Date: Jun. 23, 2016

(54) SILICON ETCH AND CLEAN

(71) Applicant: Lam Research Corporation, Fremont, CA (US)

(72) Inventors: Tom A. Kamp, San Jose, CA (US); Alexander M. Paterson, San Jose, CA (US); Neema Rastgar, Fremont, CA (US)

(21) Appl. No.: 14/576,978

(22) Filed: Dec. 19, 2014

(51) Int. Cl. H01L 21/3065; H01J 37/32; H01L 21/67

(52) U.S. Cl. CPC H01L 21/3065; H01L 21/67069; H01J 37/32082; H01J 37/32449; H01J 37/32926; H01J 2237/334

(57) ABSTRACT

A method for etching features into a silicon containing etch layer is provided. The etch layer is placed into a plasma processing chamber. An etch gas is flowed into the plasma processing chamber. The etch gas is formed into an etch plasma, wherein the etch plasma etches features into the silicon containing layer leaving silicon containing residue. The flow of etch gas into the plasma processing chamber is stopped. A dry clean gas is flowed into the plasma processing chamber, wherein the dry clean gas comprises NH₃ and NF₃. The dry clean gas is formed into a plasma, wherein the silicon containing residue is exposed to the dry clean gas plasma, and wherein at least some or all of the silicon containing residue is formed into ammonium containing compounds. The flow of the dry clean gas is stopped. The ammonium compounds are sublimated from the films.

### BACKGROUND OF THE INVENTION

The present invention relates to the manufacturing of semiconductor devices. More specifically, the invention relates to the etching and cleaning of a silicon layer.

During semiconductor wafer processing, features may be etched through a silicon layer. Such an etch process may form residue or passivation.

### SUMMARY OF THE INVENTION

To achieve the foregoing and in accordance with the purpose of the present invention, a method for etching features into a silicon containing etch layer is provided. The etch layer is placed into a plasma processing chamber. An etch gas is flowed into the plasma processing chamber. The etch gas is formed into an etch plasma, wherein the silicon containing etch layer is exposed to the etch plasma, and wherein the etch plasma etches features into the silicon containing layer leaving silicon containing residue. The flow of etch gas into the plasma processing chamber is stopped. A dry clean gas is flowed into the plasma processing chamber, wherein the dry clean gas comprises NH₃ and NF₃. The dry clean gas is formed into a plasma, wherein the silicon containing residue is exposed to the dry clean gas plasma, and wherein at least some of the silicon containing residue is formed into ammonium containing compounds. The flow of the dry clean gas is stopped. The etch layer is removed from the plasma processing chamber.

In another manifestation of the invention, a method for etching features into a silicon containing etch layer is provided. The etch layer is placed into a plasma processing chamber. A halogen containing etch gas is flowed into the plasma processing chamber. The halogen containing etch gas is formed into an etch plasma, wherein the silicon containing etch layer is exposed to the etch plasma, and wherein the etch plasma etches features into the silicon containing layer leaving silicon containing residue, wherein the silicon containing residues comprise at least one of silicon oxide, SiBrₓ, SiClₓ, SiON, SiOₓF_{y}, SiCO, SiOₓCl_{y}, or SiOₓBr_{y}, where x and y are positive integers. The flow of etch gas into the plasma processing chamber is stopped. A dry clean gas is flowed into the plasma processing chamber, wherein the dry clean gas comprises NH₃ and NF₃, wherein the dry clean gas has a ratio of the flow of NH₃ to NF₃ of between 1:1 to 20:1. The dry clean gas is formed into a plasma, wherein the silicon containing residue is exposed to the dry clean gas plasma, and wherein at least some of the silicon containing residue is formed into ammonium containing compounds. The flow of the dry clean gas is stopped. The ammonium containing compounds are sublimated at a temperature between 60° to 220° C. The etch layer is removed from the plasma processing chamber.

In another manifestation of the invention, an apparatus for etching features into a silicon containing etch layer is provided. A plasma processing chamber is provided, which comprises a chamber wall forming a plasma processing chamber enclosure, a substrate support for supporting a wafer within the plasma processing chamber enclosure, a pressure regulator for regulating the pressure in the plasma processing chamber enclosure, at least one electrode for providing power to the plasma processing chamber enclosure for sustaining a plasma, a gas inlet for providing gas into the plasma processing chamber enclosure, and a gas outlet for exhausting gas from the plasma processing chamber enclosure. At least one RF power source is electrically connected to the at least one electrode. A heater is connected to the plasma processing chamber for heating the silicon containing etch layer. A gas source is in fluid connection with the gas inlet, the gas source and comprises an etch gas source, a NH₃ gas source, and a NF₃ gas source. A controller is controllably connected to the gas source and the at least one RF power source and comprises at least one processor and computer readable media. The computer readable media comprises computer readable code for flowing an etch gas from the etch gas source into the plasma processing chamber, computer readable code for transforming the etch gas into an etch plasma, which etches features into the silicon containing etch layer leaving silicon containing residue, computer readable code for stopping the flow of the etch gas, computer readable code for flowing a dry clean gas comprising NH₃ from the NH₃ gas source and NF₃ from the NF₃ gas source into the plasma processing chamber, computer readable code for transforming the dry clean gas into an dry clean plasma, which transforms at least some of the silicon containing residue into ammonium containing compounds, computer readable code for stopping the flow of the dry clean gas, and computer readable code for heating the silicon containing etch layer, which sublimates the ammonium containing compounds.

These and other features of the present invention will be described in more detail below in the detailed description of the invention and in conjunction with the following figures.

### BRIEF DESCRIPTION OF THE DRAWINGS

The present invention is illustrated by way of example, and not by way of limitation, in the figures of the accompanying drawings and in which like reference numerals refer to similar elements and in which:

FIG. 1 is a high level flow chart of an embodiment of the invention.

FIGS. 2A-D are schematic views of a stack processed according to an embodiment of the invention.

FIG. 3 is a schematic view of an etch reactor that may be used for etching.

FIG. 4 illustrates a computer system, which is suitable for implementing a controller used in embodiments of the present invention.

### DETAILED DESCRIPTION OF THE PREFERRED EMBODIMENTS

The present invention will now be described in detail with reference to a few preferred embodiments thereof as illustrated in the accompanying drawings. In the following description, numerous specific details are set forth in order to provide a thorough understanding of the present invention. It will be apparent, however, to one skilled in the art, that the present invention may be practiced without some or all of these specific details. In other instances, well known process steps and/or structures have not been described in detail in order to not unnecessarily obscure the present invention.

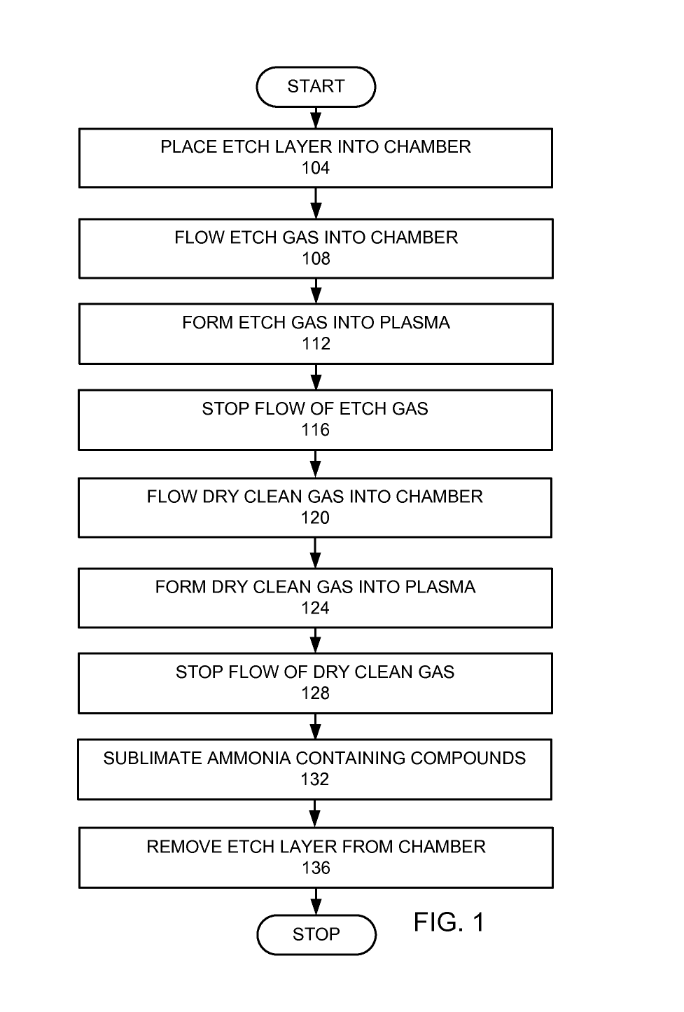

To facilitate understanding, FIG. 1 is a high level flow chart of a process used in an embodiment of the invention. An etch layer is placed in a plasma processing chamber (step 104). An etch gas is flowed into the plasma processing chamber (step 108). The etch gas is formed into a plasma (step 112), which etches the etch layer and forms a residue, which may be passivation. The flow of the etch gas is stopped (step 116). A dry clean gas comprising NH₃ and NF₃ is flowed into the plasma processing chamber (step 120). The dry clean gas is formed into a plasma (step 124), which converts the silicon etch residue into ammonia containing compounds. The flow of the dry clean gas is stopped (step 128). The layer is heated, and the ammonia containing compounds are sublimated (step 132). The etch layer is removed from the plasma processing chamber (step 136).

### Examples

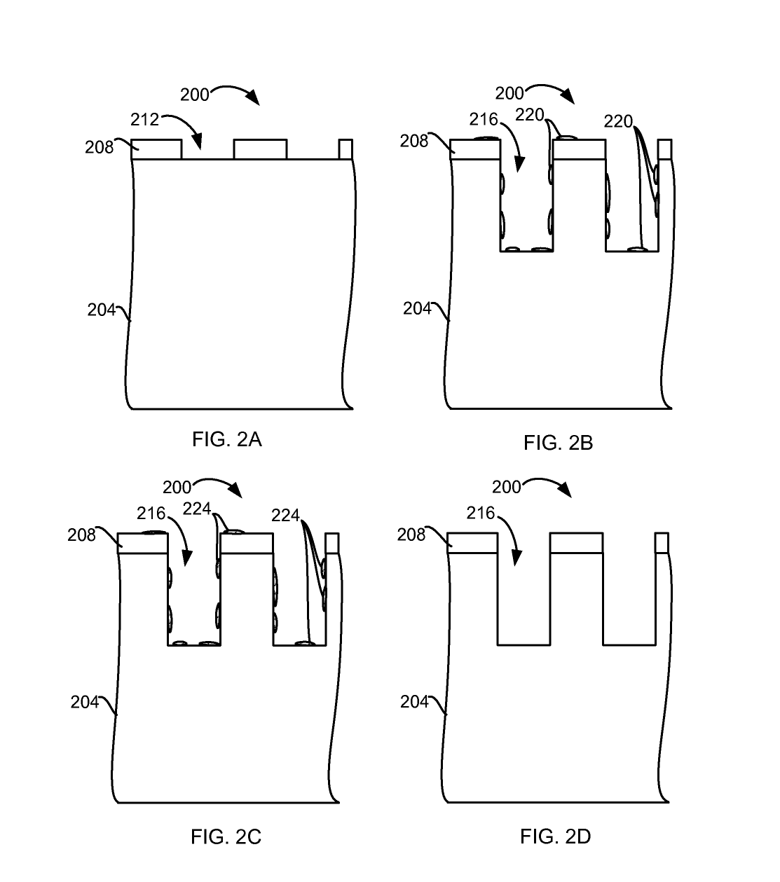

In an example of a preferred embodiment of the invention, a layer is placed into a plasma processing chamber (step 104). FIG. 2A is a cross-sectional view of a stack 200 with a silicon containing etch layer 204 disposed below a mask 208 with mask features 212. In this example, the etch layer 204 is a silicon wafer. In other embodiments the etch layer may be a silicon or polysilicon layer formed above a silicon wafer.

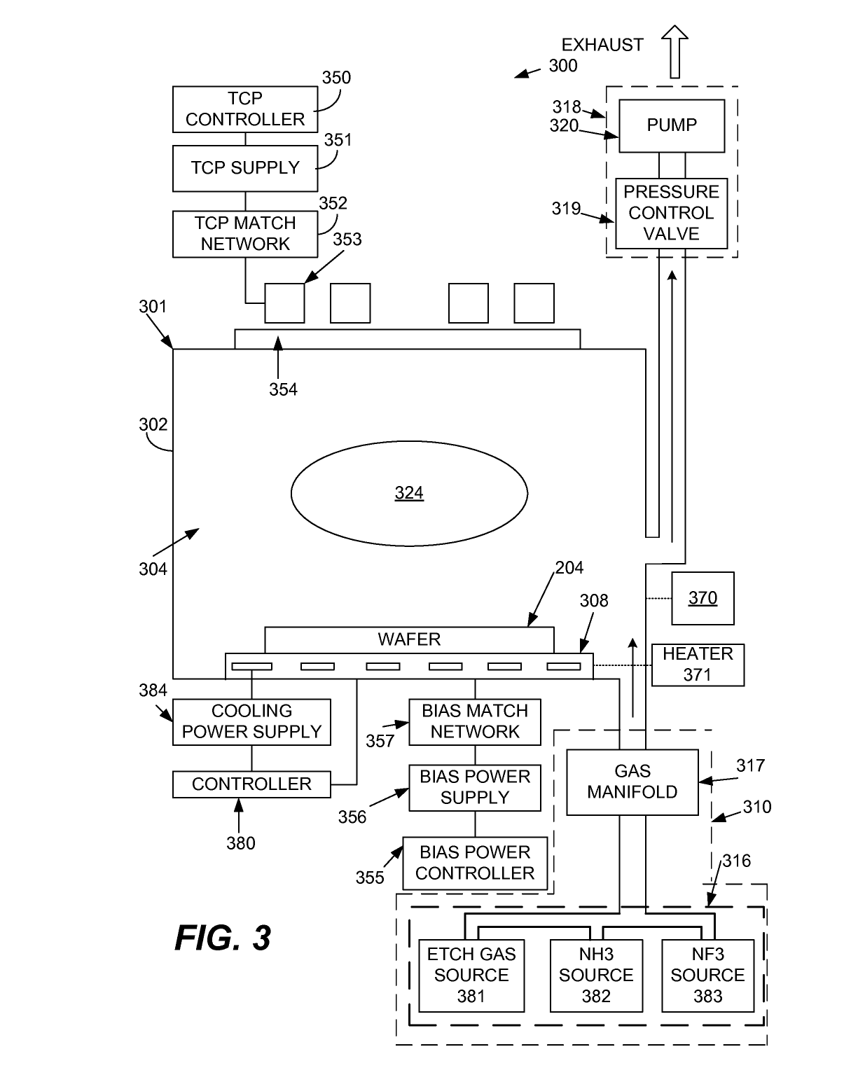

In one embodiment, all processing may be performed in a single plasma etch chamber. FIG. 3 is a schematic view of a plasma processing system 300, including a plasma processing tool 301. The plasma processing tool 301 is an inductively coupled plasma etching tool and includes a plasma reactor 302 having a plasma processing chamber 304 therein. A transformer coupled power (TCP) controller 350 and a bias power controller 355, respectively, control a TCP supply 351 and a bias power supply 356 influencing the plasma 324 created within plasma processing chamber 304.

The TCP controller 350 sets a set point for TCP supply 351 configured to supply a radio frequency signal at 13.56 MHz, tuned by a TCP match network 352, to a TCP coil 353 located near the plasma processing chamber 304. An RF transparent window 354 is provided to separate TCP coil 353 from plasma processing chamber 304, while allowing energy to pass from TCP coil 353 to plasma processing chamber 304.

The bias power controller 355 sets a set point for bias power supply 356 configured to supply an RF signal, tuned by bias match network 357, to a chuck electrode 308 located within the plasma processing chamber 304 creating a direct current (DC) bias above electrode 308 which is adapted to receive the wafer with the feature layer 204, being processed.

A gas supply mechanism or gas source 310 includes a source or sources of gas or gases 316 attached via a gas manifold 317 to supply the proper chemistry required for the process to the interior of the plasma processing chamber 304. In this example, the gas source 316 comprises at least an etch gas source 381, and NH₃ gas source 382, and an NF₃ gas source 383. A gas exhaust mechanism 318 includes a pressure control valve 319 and exhaust pump 320 and removes particles from within the plasma processing chamber 304 and maintains a particular pressure within plasma processing chamber 304.

A temperature controller 380 controls the temperature of a cooling recirculation system provided within the chuck electrode 308 by controlling a cooling power supply 384. The plasma processing system also includes electronic control circuitry 370, which may be used to control the bias power controller 355, the TCP controller 350, the temperature controller 380, and other control systems. A heater 371 is provided to heat the chuck electrode 308 in order to heat the silicon containing etch layer 204. The plasma processing system 300 may also have an end point detector. An example of such an inductively coupled system is the Kiyo built by Lam Research Corporation of Fremont, CA, which is used to etch silicon, polysilicon and conductive layers. In other embodiments of the invention, a capacitively coupled system may be used.

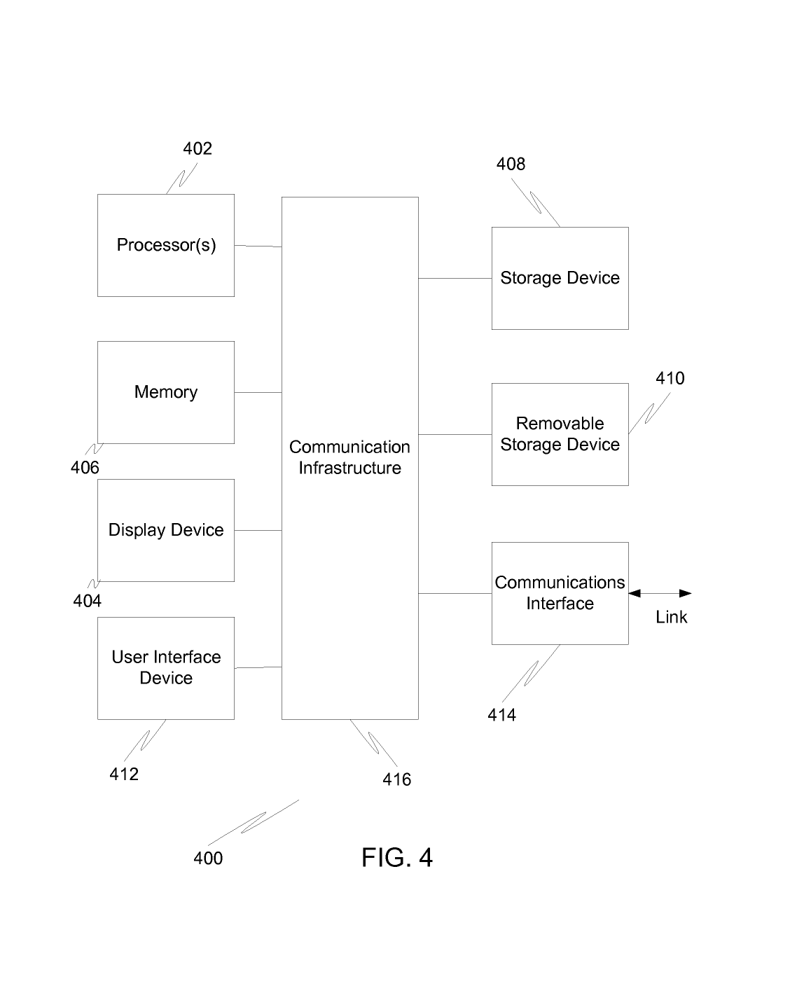

FIG. 4 is a high level block diagram showing a computer system 400, which is suitable for implementing a control circuitry 370 used in embodiments of the present invention. The computer system may have many physical forms ranging from an integrated circuit, a printed circuit board, and a small handheld device up to a huge super computer. The computer system 400 includes one or more processors 402, and further can include an electronic display device 404 (for displaying graphics, text, and other data), a main memory 406 (e.g., random access memory (RAM)), storage device 408 (e.g., hard disk drive), removable storage device 410 (e.g., optical disk drive), user interface devices 412 (e.g., keyboards, touch screens, keypads, mice or other pointing devices, etc.), and a communication interface 414 (e.g., wireless network interface). The communication interface 414 allows software and data to be transferred between the computer system 400 and external devices via a link. The system may also include a communications infrastructure 416 (e.g., a communications bus, cross-over bar, or network) to which the aforementioned devices/modules are connected.

Information transferred via communications interface 414 may be in the form of signals such as electronic, electromagnetic, optical, or other signals capable of being received by communications interface 414, via a communication link that carries signals and may be implemented using wire or cable, fiber optics, a phone line, a cellular phone link, a radio frequency link, and/or other communication channels. With such a communications interface, it is contemplated that the one or more processors 402 might receive information from a network, or might output information to the network in the course of performing the above-described method steps. Furthermore, method embodiments of the present invention may execute solely upon the processors or may execute over a network such as the Internet in conjunction with remote processors that shares a portion of the processing.

The term “non-transient computer readable medium” is used generally to refer to media such as main memory, secondary memory, removable storage, and storage devices, such as hard disks, flash memory, disk drive memory, CD-ROM and other forms of persistent memory and shall not be construed to cover transitory subject matter, such as carrier waves or signals. Examples of computer code include machine code, such as produced by a compiler, and files containing higher level code that are executed by a computer using an interpreter. Computer readable media may also be computer code transmitted by a computer data signal embodied in a carrier wave and representing a sequence of instructions that are executable by a processor.

An etch gas is flowed from the etch gas source 381 into the plasma processing chamber 304 (step 108). In this embodiment, the etch gas comprises halogen containing component. An example of a etch gas recipe would be HBr and O₂.

The etch gas is formed into a plasma (step 112). In this example, TCP power at 13.5 MHz is provided to form the etch gas into a plasma. The etch layer 204 is etched by the plasma. A bias of 0-3000 volts is provided. When the desired etching is completed by the plasma, the flow of the etch gas is stopped (step 116).

FIG. 2B is a cross-sectional schematic view of the stack 200 after the etch layer has been etched forming etch features 216. The etch process has created a silicon containing residue 220, which may be a silicon containing passivation. The silicon containing residue may be silicon oxide (SiO or SiO₂), SiBrₓ, SiClₓ, SiON, SiOₓF_{y}, SiCO, SiOₓCl_{y}, or SiOₓBr_{y}, where x and y are positive integers. Preferably, the silicon containing residues comprise both silicon and oxygen.

In order to clean the silicon containing residue, a dry clean gas is flowed from the gas source 316 into the plasma processing chamber 304 (step 120). In this example, the dry clean gas comprises 50 to 1500 sccm NH₃ from the NH₃ gas source 382 and 10-500 sccm NF₃ from the NF₃ gas source.

The dry clean gas is formed into a plasma (step 124). In this example, TCP power at 13.5 MHz is provided to form the dry clean gas into a plasma. A bias of 0 to 500 volts is provided. The etch layer is maintained at −20-120° C. The recipe provides a low density, low energy, and low bias plasma. The plasma from the dry clean gas converts the silicon residue into ammonium containing compounds. The flow of the dry clean gas is stopped (step 128). FIG. 2C is a cross-sectional schematic view of the stack 200 after the silicon residue has been converted to ammonium containing compounds 224. Preferably, the etch layer 204 is not etched during this process.

The ammonia containing compounds 224 are sublimated (step 132). In this example, the etch layer 204 or stack 200 is heated to a temperature that sublimates the ammonia containing compounds 224. In this example the etch layer 204 or stack 200 is heated to a temperature of 200° C. FIG. 2D is a cross-sectional schematic view of the stack 200 after the ammonium containing compounds have been sublimated.

This example provides a method and apparatus for providing a silicon etch and removing the resulting silicon residue in the same chamber. Such a process eliminates a need for a separate wet cleaning process, which requires transferring the wafer to a wet bath.

Preferably, the dry clean gas comprises NH₃ and NF₃. More preferably, the dry clean gas comprises NH₃, NF₃, and a noble gas. The ammonium containing compounds preferably comprise NH₄F, NH₄Br, or NH₄Cl. Depending on the passivation residue being removed, examples of reactions may be the following:

NF₃+NH₃→NH₄F+NH₄F.HF

NH₄F or NH₄F.HF+SiO₂→(NH₄)₂SiF₆(Solid)+H₂O

(NH₄)₂SiF₆(Solid)→SiF₄(gas)+NH₃(gas)+HF(gas)

Preferably, the dry clean process provides a bias of between 0 to 1000 volts. More preferably, the dry clean process provides a bias between 0 to 500 volts. Preferably, during the dry clean, NH₃ has a flow rate of 50 to 1500 sccm. Preferably, during the dry clean, NF₃ has a flow rate of 10 to 500 sccm. Preferably, the flow ratio of NH₃ to NF₃ is from 1:1 to 20:1. More, preferably, the flow ratio of NH₃ to NF₃ is from 1:1 to 15:1. Preferably, the dry cleaning process is accomplished at a temperature of between −20° C. to 120° C.

Preferably, the sublimation is accomplished by heating the etch layer to a temperature of greater than 60° C. More preferably, the sublimation is accomplished by heating the etch layer to a temperature of between 60° C. to 220° C.

Preferably, during the formation of the etch plasma a bias of 0-3000 volts is provided and the etch layer is maintained at a temperature between −20° to 120° C.

In a preferred embodiment, the etched features are formed into shallow trench isolation. In another preferred embodiment, the etched features are used to form a gate. In other embodiments, the etched features may be used to form a source or drain. More preferably, the silicon containing layer is pure silicon or pure silicon with a dopant. Most preferably, the silicon containing layer is silicon.

In another embodiment the etch layer is removed from the chamber before the ammonium containing compounds are sublimated. In such an embodiment, a subsequent high temperature process outside of the plasma processing chamber, such as an anneal process, may be used to sublimate the ammonium containing compounds.

While this invention has been described in terms of several preferred embodiments, there are alterations, permutations, modifications, and various substitute equivalents, which fall within the scope of this invention. It should also be noted that there are many alternative ways of implementing the methods and apparatuses of the present invention. It is therefore intended that the following appended claims be interpreted as including all such alterations, permutations, and various substitute equivalents as fall within the true spirit and scope of the present invention.

1. A method for etching features into a silicon containing etch layer, comprising
placing the etch layer into a plasma processing chamber;
flowing an etch gas into the plasma processing chamber;
forming the etch gas into an etch plasma, wherein the silicon containing etch layer is exposed to the etch plasma, and wherein the etch plasma etches features into the silicon containing layer leaving silicon containing residue;
stopping the flow of etch gas into the plasma processing chamber;
flowing a dry clean gas into the plasma processing chamber, wherein the dry clean gas comprises NH₃ and NF₃;
forming the dry clean gas into a non-remote plasma, wherein the silicon containing residue is exposed to the dry clean gas non-remote plasma, and wherein at least some of the silicon containing residue is formed into ammonium containing compounds;
stopping the flow of the dry clean gas; and
removing the etch layer from the plasma processing chamber.

2. The method, as recited in claim 1, wherein the dry clean gas further comprises a noble gas.

3. The method, as recited in claim 2, further comprising sublimating the ammonium containing compounds before removing the layer from the plasma processing chamber.

4. The method, as recited in claim 3, wherein the dry clean gas has a ratio of the flow of NH₃ to NF₃ of between 1:1 to 20:1.

5. The method, as recited in claim 4, during the forming the dry clean gas into a plasma a bias of between 0 to 1000 volts is provided.

6. The method, as recited in claim 5, wherein during the sublimating the ammonium containing compounds the etch layer is maintained at a temperature between 60° to 220° C.

7. The method, as recited in claim 6, wherein the etch layer is a silicon substrate, silicon wafer, a gate, a shallow trench isolation layer, a source layer, a drain layer, or a polysilicon layer.

8. The method, as recited in claim 7, wherein the etch gas is a halogen containing etch gas.

9. The method, as recited in claim 1, further comprising sublimating the ammonium containing compounds before removing the layer from the plasma processing chamber.

10. The method, as recited in claim 9, wherein during the sublimating the ammonium containing compounds the etch layer is maintained at a temperature between 60° to 220° C.

11. The method, as recited in claim 1, wherein the dry clean gas has a ratio of the flow of NH₃ to NF₃ of between 1:1 to 20:1.

12. The method, as recited in claim 1, during the forming the dry clean gas into a plasma a bias of between 0 to 1000 volts is provided.

13. A method for etching a silicon substrate, silicon wafer, a source layer, a drain layer, or a polysilicon layer, comprising
placing the silicon substrate, silicon wafer, the source layer, the drain layer, or the polysilicon layer into a plasma processing chamber;
flowing an etch gas into the plasma processing chamber;
forming the etch gas into an etch plasma, wherein the silicon substrate, silicon wafer, the source layer, the drain layer, or the polysilicon layer is exposed to the etch plasma, and wherein the etch plasma etches features into the silicon substrate, silicon wafer, the source layer, the drain layer, or the polysilicon layer leaving silicon containing residue;
stopping the flow of etch gas into the plasma processing chamber;
flowing a dry clean gas into the plasma processing chamber, wherein the dry clean gas comprises NH₃ and NF₃;
forming the dry clean gas into a plasma, wherein the silicon containing residue is exposed to the dry clean gas plasma, and wherein at least some of the silicon containing residue is formed into ammonium containing compounds;
stopping the flow of the dry clean gas; and
removing the silicon substrate, silicon wafer, a source layer, the drain layer, or the polysilicon layer from the plasma processing chamber.

14. The method, as recited in claim 1, wherein the etch gas is a halogen containing etch gas.

15. The method, as recited in claim 1, wherein the silicon containing residues comprise at least one of silicon oxide, SiBrₓ, SiClₓ, SiON, SiOₓF_{y}, SiCO, SiOₓCl_{y}, or SiOₓBr_{y}, where x and y are positive integers.

16. A method for etching features into a silicon containing etch layer, comprising
placing the etch layer into a plasma processing chamber;
flowing a halogen containing etch gas into the plasma processing chamber;
forming the halogen containing etch gas into an etch plasma, wherein the silicon containing etch layer is exposed to the etch plasma, and wherein the etch plasma etches features into the silicon containing layer leaving silicon containing residue, wherein the silicon containing residues comprise at least one of silicon oxide, SiBrₓ, SiClₓ, SiON, SiOₓF_{y}, SiCO, SiOₓCl_{y}, or SiOₓBr_{y}, where x and y are positive integers;
stopping the flow of etch gas into the plasma processing chamber;
flowing a dry clean gas into the plasma processing chamber, wherein the dry clean gas comprises NH₃ and NF₃, wherein the dry clean gas has a ratio of the flow of NH₃ to NF₃ of between 1:1 to 20:1;
forming the dry clean gas into a non-remote plasma, wherein the silicon containing residue is exposed to the dry clean gas non-remote plasma, and wherein at least some of the silicon containing residue is formed into ammonium containing compounds;
stopping the flow of the dry clean gas;
sublimating the ammonium containing compounds at a temperature between 60° to 220° C.; and
removing the etch layer from the plasma processing chamber.

17. The method, as recited in claim 16, wherein the etch layer is a silicon substrate, silicon wafer, a gate, a shallow trench isolation layer, a source layer, a drain layer, or a polysilicon layer.

18. An apparatus for etching features into a silicon containing etch layer, comprising:
a plasma processing chamber, comprising:
a chamber wall forming a plasma processing chamber enclosure;
a substrate support for supporting a wafer within the plasma processing chamber enclosure;
a pressure regulator for regulating the pressure in the plasma processing chamber enclosure;
at least one electrode for providing power to the plasma processing chamber enclosure for sustaining a plasma;
a gas inlet for providing gas into the plasma processing chamber enclosure; and
a gas outlet for exhausting gas from the plasma processing chamber enclosure;
at least one RF power source electrically connected to the at least one electrode;
a heater for heating the silicon containing etch layer
a gas source in fluid connection with the gas inlet, the gas source comprising:
an etch gas source;
a NH₃ gas source; and
a NF₃ gas source; and
a controller controllably connected to the gas source and the at least one RF power source, comprising:
at least one processor; and
computer readable media, comprising:
computer readable code for flowing an etch gas from the etch gas source into the plasma processing chamber;
computer readable code for transforming the etch gas into an etch plasma, which etches features into the silicon containing etch layer leaving silicon containing residue;
computer readable code for stopping the flow of the etch gas;
computer readable code for flowing a dry clean gas comprising NH₃ from the NH₃ gas source and NF₃ from the NF₃ gas source into the plasma processing chamber;
computer readable code for transforming the dry clean gas into an dry clean plasma, which transforms at least some of the silicon containing residue into ammonium containing compounds;
computer readable code for stopping the flow of the dry clean gas; and
computer readable code for heating the silicon containing etch layer, which sublimates the ammonium containing compounds.
